(19) United States
(12) Patent Application Publication
(10) Pub. No.: US 2025/0324909 A1
(43) Pub. Date: Oct. 16, 2025

(54) UNIPOLAR THERMOELECTRIC GENERATOR WITH VERTICAL INTERCONNECTS AND THERMAL FOCUSING

(71) Applicant: ATS IP, LLC, Fort Collins, CO (US)

(72) Inventors: Ronald Petkie, Fort Collins, CO (US); Jake Perez, Fort Collins, CO (US); Ion Basa, Fort Collins, CO (US); John Newman, Fort Collins, CO (US); Kelly Adams, Edmonton, Alberta (CA)

(21) Appl. No.: 18/855,307

(22) PCT Filed: Apr. 14, 2023
(86) PCT No.: PCT/US2023/018689

§ 371 Date: Oct. 8, 2024

Related U.S. Application Data
(63) Continuation of application No. 18/151,296, filed on Jan. 6, 2023.
(60) Provisional application No. 63/331,715, filed on Apr. 15, 2022.

(51) Int. Cl. H10N 10/17; C25D 3/12; C25D 7/12; H10N 10/01; H10N 10/817; H10N 10/82

(52) U.S. Cl. CPC H10N 10/17; C25D 3/12; C25D 7/123; H10N 10/01; H10N 10/817; H10N 10/82

(57) ABSTRACT

The embodiments presented herein provide for significantly increasing TEG device output power. In one embodiment, a TEG includes a plurality of pairs of P type semiconductor pellets configured on a substrate and interconnected by vertical and horizontal interconnects. The TEG also includes an N type semiconductor pellet configured on the substrate, and an electrode. The N type semiconductor pellet is operable to reverse electrical current to at least one of the P type semiconductor pellets through the electrode.

### CROSS REFERENCE TO RELATED APPLICATIONS

This patent application claims priority to, and thus the benefit of an earlier filing date from, U.S. Provisional Patent Application No. 63/331,715 (filed Apr. 15, 2022), the contents of which are hereby incorporated by reference. This patent application is also related to commonly owned and copending U.S. patent application Ser. No. 18/151,296 (filed Jan. 6, 2023), the contents of which are hereby incorporated by reference.

### BACKGROUND

Thermoelectric generators (TEGs) have been the subject of research for decades. TEGs can be used for alternative power generation in the Seebeck mode, which converts a heat flux into electrical flux. Inversely, in the Peltier mode, electrical flux can be used to drive a heat flux gradient to provide refrigeration.

Thermoelectric devices for power generation are drivers of research because waste heat, which is otherwise lost to the environment, can be recycled into electrical energy, and used in a remote location or fed back into the electrical grid through inverters. However, this approach for electrical power generation has met barriers in terms of a fundamental parameter—i.e., the cost per watt, when compared to other methods of power generation, such as solar technology. The major reasons for this cost barrier are inherent to the thermoelectric properties of the semiconductor in the devices, and the cost of manufacturing of a heat exchanger system to provide hot and cold surfaces required for conversion of the heat energy into electrical energy. However, TEGs can continually operate at optimized maximum power, while solar technology can operate only during the day. Solar energy output also varies in accordance with geographic locations and weather patterns. Thus, progress in all aspects of manufacturing of TEGs is vital if thermoelectric energy production methods are to unfold on a ubiquitous and large scale for clean energy conversion, namely in the megawatt power range and above.

### SUMMARY

The embodiments presented herein provide for significantly increasing TEG device output power. In this regard, the described embodiments relate generally to TEG devices made from semiconductor components and metal interconnects. In one embodiment, a TEG circuit is comprised of a series arrangement of alternating P type (i.e., hole carriers) and N type (i.e., electron carriers) pellets for the convenience of fabrication. The shape of the semiconductor pellets is generally cuboid or cylindrical (e.g., pellet), though the shape can have any form that allows for thermal focusing effects (a.k.a. thermal lensing), such as a rectangular, parallelepiped, spherical, truncated cone, or other polyhedrons. Two metal electrodes on opposite sides of the cuboid pellet are used for attaching to the metal/electrical interconnects. This includes the joining of two flat surfaces of the pellet and the interconnect, where the surface of the interconnect may be printed with a solder paste for a robust electrical contact to the pellet.

To increase TEG performance by a significant factor (e.g., roughly 1.6×) the electrode geometry adjacent to the semiconductor pellet used in the surface mount component assembly of a TEG module is modified. The benefits of a thermal lensing electrode were shown through computational multi-physics with Comsol. An increase in performance is achieved by thermal and electrical injection into the bulk of the semiconductor pellet through the sidewalls of the pellet. Contrary to the traditional fabrication methods, there is an advantage to metallize the sidewalls of a semiconductor pellet as long as the metal thickness is at least preferably greater than about 0.5 mm, and thermal conductivity has a relatively high value, like that of copper.

Furthermore, leaving a small gap, or slit, in the metallization of the sidewalls between the top and bottom metal electrode results in significantly increased thermoelectric power generation through thermal lensing. This effect may depend on the difference of the thermal conductivity between the semiconductor and the metal sidewall. Since the telluride thermoelectric materials have a relatively low thermal conductivity (e.g., about 0.5 W/m-K), and the sidewall metallization is copper (e.g., about 400 W/m-K), the requirements are satisfied. Heat is easily transferred therewithin the semiconductor, where isotherm curvature is introduced. Computational analysis of a copper (or nickel) sidewall metallization, with a thickness of about 1 mm, and as a function of sidewall height as the fraction of the pellet height, yielded improved results. The analysis included a gap width of about 50 microns on all four sidewalls of a cuboid shape of a telluride-based thermoelectric pellet, positioned symmetrically.

In one embodiment, a TEG includes a plurality of pairs of P type semiconductor pellets configured on a substrate and interconnected by vertical and horizontal interconnects. The TEG also includes an N type semiconductor pellet configured on the substrate, and an electrode. The N type semiconductor pellet is operable to reverse electrical current to at least one of the P type semiconductor pellets through the electrode. In some embodiments, the P type semiconductor pellets have a zT value of about 2.6.

The vertical interconnects may be configured from graphene oxide, reduced graphene oxide, an aerogel, a metal sidewall on an insulator, a metal doped BiTe pellet, or other high electrical, low thermal conductivity material. The vertical interconnects may be operable to direct electrical current as a top-to-bottom series circuit between neighboring P type semiconductor pellet pairs. The vertical interconnects may be shaped (e.g., z-shaped strip, a cuboid, a cylinder, a sphere, a trapezoid, or a pyramid).

In some embodiments, the P type semiconductor pellets are metallized with a metal layer surrounding each of the P type semiconductor pellets. Each metal layer may include an aperture that exposes its respective P type semiconductor pellet about a perimeter of the P type semiconductor pellet at a predetermined sidewall height of the P type semiconductor pellet. The apertures may provide a non-linear effect on a power output of the TEG by modifying an isotherm surface curvature within the P type semiconductor pellets. The isotherm surface curvature within the P type semiconductor pellets is operable to increase an effective surface area of a thermoelectric effect within a volume of the P type semiconductor pellets via heat injection through the sidewall of the P type semiconductor pellets.

The metal layer remains at the sidewall of each P type semiconductor pellet. The metal layer may be copper, titanium, tungsten, nickel-phosphorous, or a chromium alloy. The aperture may electrically isolate a top portion of the metal layer from a bottom portion of the metal layer of each P type semiconductor pellet. In some embodiments, the TEG may include a plurality of metal containers, each being thermally and electrically bonded to the metal layer of one of the P type semiconductor pellets. The metal containers are configured between the metal layers and the substrate.

In other embodiments, the P type semiconductor pellets are configured with a non-metal layer that is thermally conductive and electrically insulative surrounding each of the P type semiconductor pellets. Each non-metal layer comprises an aperture that exposes its respective P type semiconductor pellet about a perimeter of the P type semiconductor pellet at a predetermined sidewall height of the P type semiconductor pellet. And the non-metal layer remains at the sidewall of each P type semiconductor pellet. The non-metal layer may be configured of a thermally conductive high temperature epoxies and adhesives.

In some embodiments, the P type semiconductor pellets are configured in a shape that is operable to increase a thermal lensing effect of the TEG (e.g., cuboid or cylindrical).

The various embodiments disclosed herein may be implemented in a variety of ways as a matter of design choice. For example, some embodiments herein are implemented in hardware whereas other embodiments may include processes that are operable to implement and/or operate the hardware. Other exemplary embodiments, including software and firmware, are described below.

### BRIEF DESCRIPTION OF THE FIGURES

Some embodiments of the present invention are now described, by way of example only, and with reference to the accompanying drawings. The same reference number represents the same element or the same type of element on all drawings.

FIG. 1 is a perspective view of a unipolar TEG package with vertical interconnects.

FIG. 2 is another perspective view of the TEG package of FIG. 1 illustrating P type and N type semiconductor pellet pairs.

FIG. 3 is an overhead view of a TEG package illustrating the voltage throughput.

FIG. 4 is a graph illustrating the ZT figure of merit of P type and N type pellets as a function of temperature.

FIG. 5 is a graph illustrating thermal conductivity of P type and N type pellets.

FIG. 6 is a graph illustrating how the electrical conductivity of vertical interconnect improves the power output.

FIG. 7 is a graph illustrating resistivity of P type and N type pellets and the ratio of P type and N type pellets as a function of temperature.

FIG. 8 is a perspective view of a TEG package illustrating details of the vertical and horizontal interconnects.

FIG. 9 is an overhead view of a TEG package illustrating power density as a function of electrical conductivity (GL) and resistive load (RL).

FIG. 10 is an exploded view of a TEG package illustrating power density of the TEG package.

FIG. 11 is another overhead view of a TEG package.

FIG. 12 is a perspective and exploded view of a TEG package shown without the upper plate and with one N type pellet highlighted that reverses current at an output electrode.

FIG. 13 is a perspective and exploded view of a TEG package shown without the upper plate and illustrating vertical interconnects between P type pellet pairs.

FIG. 14 is a cross sectional view of a TEG package illustrating a curvature of the power density distribution induced by the TEG package components.

FIG. 15 is a perspective and exploded view of a TEG package shown without the upper plate and size variations in the output electrodes.

FIG. 16 is a graph illustrating power output of the TEG package as a function of electrical conductivity (GL) and the thermal conductivity (TL).

FIG. 17 is a block diagram of an exemplary computing system in which a computer readable medium provides instructions for performing methods herein.

### DETAILED DESCRIPTION OF THE FIGURES

The figures and the following description illustrate specific exemplary embodiments. It will thus be appreciated that those skilled in the art will be able to devise various arrangements that, although not explicitly described or shown herein, embody certain principles and are included within the scope of the embodiments. Furthermore, any examples described herein are intended to aid in understanding the embodiments and are to be construed as being without limitation to such specifically recited examples and conditions. As a result, the embodiments are not limited to any of the examples described below.

Electrical components, referred to herein as vertical interconnects, are used to couple together pairs of high performing P type pellets 104 in a thermal lensing component. These vertical interconnects can be made in different ways to accommodate production. A TEG power output and efficiency per semiconductor material volume can be significantly increased in terms of effective power density when compared to the conventional method of fabricating a TEG using P type and N type pellet pairs. The mass of semiconductor material is dramatically reduced by using a TLEC to achieve the higher power output and efficiency when compared to traditional TEGs. The power output per semiconductor mass increases the efficacy of thermoelectric materials in general, an advantage in making thermoelectric technology more available to the conversion of heat flux to electrical flux in terms of the cost per watt, an important parameter in the success of adopting an alternative energy source.

In addition, the physical properties of the two types of pellets are typically not of similar performance in terms of the conversion of heat into electrical energy. It is of interest to therefore consider a TEG made from high performing pellet types. The gauge for evaluating the pellet performance is zT.

zT is a dimensionless figure of merit used in thermoelectric research to describe the efficiency of a thermoelectric material. zT is defined as S²σT/κ, where S is the Seebeck coefficient, σ is the electrical conductivity, κ is the thermal conductivity, and T is the absolute temperature. A higher zT value indicates a more efficient thermoelectric material, meaning that it can convert a larger amount of heat into electricity. Typically, a material with a zT value above 1 is considered to be a good thermoelectric material, while a zT value of 2 or higher is considered to be excellent. The embodiments herein have been used to obtain zT values as high as 2.6.

The Seebeck coefficient (a.k.a., the thermoelectric power or thermopower) is a material property that describes the magnitude of the electric potential difference that is generated across a temperature gradient in a material. When two dissimilar materials are joined together at two different temperatures, an electric potential difference is generated between them, which is proportional to the temperature difference. The Seebeck coefficient is defined as the ratio of the electric potential difference to the temperature difference between the two materials, expressed in units of microvolts per Kelvin (μV/K). The Seebeck coefficient depends on the properties of the material, such as its electronic structure, crystal structure, and carrier concentration. The Seebeck coefficient is an important parameter for the design and optimization of thermoelectric materials, which can be used to convert waste heat from power plants and other industrial processes into electricity, and/or can be used in cooling applications.

If a TEG can be constructed of P type semiconductor pellets with relatively high zT values, then it is anticipated that there would be benefits in power conversion and efficiency and/or benefits regarding the cost of material to construct the generator. Such a device may then be referred to as a unipolar TEG, though one of the pellets may be reserved for an N type pellet for redirecting the generated current at the output electrodes and completing the series circuit.

More particularly, the present embodiments relate to design improvements in the generator that utilizes relatively high performing pellets, namely P type semiconductor pellets. The thermal lensing effect is used to enhance the output through the focusing of thermal energy within the bulk of the pellet and reconfiguration of the generated thermoelectric current within the pellets. Thus, the power output of the TEG output can be increased significantly. The design regards the nature of the series circuit interconnecting the P type pellet pairs 104 and the vertical electrodes 102 are used to interconnect the pellet pairs from the bottom of one pair to the top of another pair to make a series circuit, leading to an increase in overall thermoelectric performance of the TEG.

The embodiments presented herein increases TEG device output power by a significant factor. The additional electrical components, referred to herein as vertical interconnects, are used to couple together pairs of high performing P type pellets in a thermal lensing component. These vertical interconnects 102 can be made in different ways to accommodate production. TEG power output and efficiency per semiconductor material volume can be significantly increased in terms of effective power density using P type and N type pellet pairs when compared to the conventional method of fabricating a TEG. And the amount of expensive semiconductor material is dramatically reduced by using a TLEC increase power output and efficiency when compared to traditional TEGs. The power output per semiconductor mass increases the efficacy of thermoelectric materials in general, an advantage in making thermoelectric technology more available to the conversion of heat flux to electrical flux in terms of the cost per watt. This is an important parameter in the success of adopting an alternative energy source.

One method of building a TEG is based on sequentially layered assembly of each component type using automated techniques such as robotic placement of the components with pick and place equipment. TEG modules can be made in this manner for high volume production. For example, automation for surface mount electronic packages makes for high-speed assembly. And a TEG module of about 3.5″×7″ can be constructed from component parts and produced in about 7 minutes in an automated fashion.

An active component for the thermoelectric effect is a pellet of semiconductor materials, where the materials have suitable thermoelectric properties in accordance with their dopants. Generally, two types of materials are used in fabricating the TEG device embodiments herein, one with electrons as the majority charge carrier (N type), and one with holes as the majority charge carrier (P type). In a package design (module), each pellet is a cuboid shape and has two electrodes for thermal and current injection on the top and bottom sides. Thus, the thermal gradient is parallel to the sidewalls of each pellet from the top to the bottom of the pellet for every pellet in many standard layouts. And the electrical current generated through the thermoelectric effect is parallel with the thermal gradient in each pellet. Collectively, the electrical current between the pellets in a module are connected in series, where two opposing planar electrodes provide the input and one output electrode for current flow.

The pellets herein are generally cuboid shape because a cuboid shape is an efficient space-filling shape, while cylindrical pellets are generally not. Higher packing density of active thermoelectric pellets provides more active volume in the TEG module 100 to convert heat and/or provide active cooling. Thus, many of the embodiments herein have a pellet configured with a cuboid shape in terms of module design. However, other shapes may be used as a matter of design choice.

Heat transfer into the pellets is generally limited to the top and the bottom surfaces of the pellet in packaging. The modification of thermal transfer to the semiconductor pellet enhances the effective area of heat transfer provided through the heat transfer from most of the pellet sidewalls. The increase in the effective surface area is made by modification of the isotherms internal to the pellet and results in an increase in the thermoelectric conversion of heat energy into electrical energy, resulting in a higher power output of a pellet.

The injection of heat from the sidewalls is accomplished by a layer of a relatively high thermally conductive material(s) on the sidewalls. Generally, a metal, such as copper, nickel, or silver can be made by 3D printing. Pellets are bonded to these metal structures by solder. Thicker sidewall material results in higher thermal conductance, and more heat is transferred to the interior of the pellet from the sidewalls in accordance with the high thermal conductance of the metal sidewalls. It is important that the thermal conductivity of the sidewall metal is much higher than the semiconductor pellets, and has a much higher thermal conductivity than the semiconductor pellets. This injection of heat results in a modification of the shape of the thermal gradient within the pellet. Since the thermoelectric effect depends directly on the area of thermal gradient, the modification of the thermal gradient within the pellet results in changes in the enhancement of the thermoelectric effect. The isotherms within the pellet, as defined by the thermal gradients, are no longer parallel to the top and bottom surfaces (e.g., two dimensional parallel isotherms) as in the case of no metal on the sidewalls. The injection of heat from the sidewalls changes the shape of the isotherms to curved surfaces (e.g., dome-shaped) within the pellets, having a three-dimensional shape rather than a parallel planar two-dimensional shape. Such a change in the shape of the isotherms to 3D surfaces increases the effective area of the thermoelectric effect within the bulk of the pellet through shaping of the thermal gradient, thereby increasing the power output.

Thermoelectric power generated is directly proportional to the effective surface area of the parallel isotherms within the thermoelectric pellet. Hence, more power can be generated within a pellet by this effective increase of the surface area of the isotherms without increasing the size and/or changing the shape of the pellet. And more electrical power can be converted by the direction, or focus, of heat transport. A relatively thick sidewall metallization of a semiconductor pellet may be used in the assembly of TEG modules herein. These designs utilize the P and N type semiconductor components arranged in a series electrical circuit. However, fabricating a TEG by primarily using a single type of semiconductor material rather than mixed types can improve performance. High performing semiconductors of a singular type and alternative circuit designs using new electronic components are employed in making the TEG embodiments herein. In this way, the advantages include increased output power performance with less semiconductor mass by using the higher performing semiconductor type to fabricate the TEGs herein.

These embodiments for herein increase TEG device output power through thermal lensing with higher performing semiconducting materials. In this module design, the embodiments employ additional electrical components, referred to as vertical interconnects, that couple together pairs of high performing P type pellets in a dual thermal lensing electrode component to modify the current and voltage output while reducing the risk of open circuit fabrication errors for increased reliability. Output voltage may be lower, while output current may increase. The overall power is generally greater than standard package geometries, while using less semiconductor material.

The TEG power output and efficiency per semiconductor material volume can be used to significantly decrease the amount of semiconductor mass. The semiconductor mass is replaced by a lower cost metal (copper) to induce the thermal lensing effect, and the singular use of the higher performing P type semiconductor material results in better performance. Therefore, the power output per semiconductor mass increases the efficacy of thermoelectric materials in general, an advantage in making thermoelectric technology more available to the conversion of heat flux to electrical flux. Thus, the concepts herein apply to many thermoelectric materials and involve a novel electronic design for a TEG.

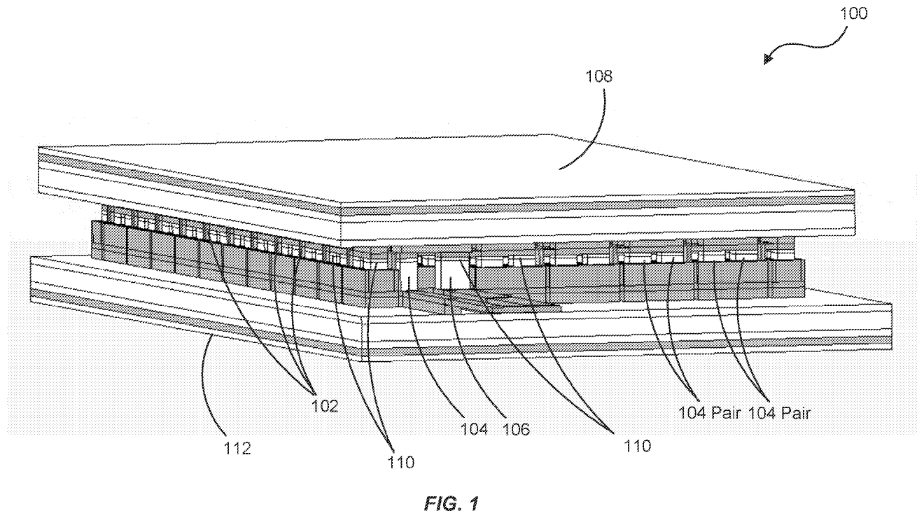

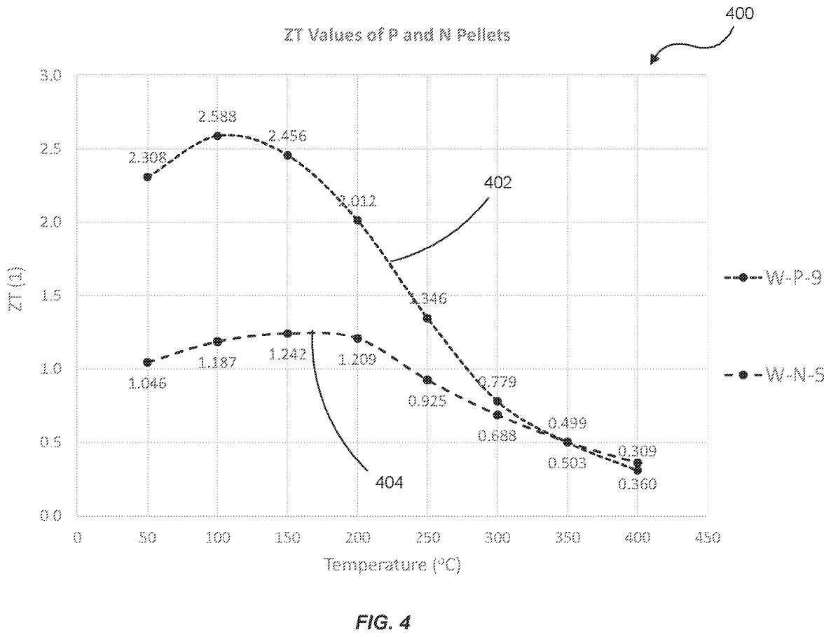

With this in mind, FIG. 1 is a perspective view of a TEG package 100 with vertical interconnects 102. In this embodiment, the TEG 100 comprises 276 pellets 104 and 106 configured on a substrate (e.g., a cold plate 112). The TEG 100 is a component-based circuit where 275 of the pellets are P type pellet (104), and one (or more) N type pellet (106) is used to redirect the current at the output electrode. However, other embodiments may be reversed (e.g., 275 N type pellets 106 and one or more P type pellets 104) as a matter of design choice. This P type thermoelectric semiconductor pellet 104 is made through an optimized sintering process. The value of zT is measured experimentally as a function of temperature, as shown in FIG. 4. Of course, the embodiments herein are not intended to be limited to the numbers of any type of pellet disclosed herein. These embodiments are merely exemplary in nature and simply show that the majority of pellets are generally of one type versus the other, thus being “unipolar” in design.

The individual physical properties of the semiconductor wafer are made from a sample that is 4 inches in diameter by about 5 mm in thickness. The semiconductor compound in most embodiments is antimony bismuth telluride with a typical zT of about 2.6 for a P type semiconductor at a temperature of 100° C. This value may be a world record for zT at 100° C. Many researchers usually report zT values at lower values and at much higher temperatures. The high value of zT at such a low temperature makes for a ready application of TEGs in the field, as high temperatures lead to reduced lifetime of the generator.

These semiconductor properties were modeled in Comsol Multiphysics software after the physical properties were measured using temperature averaging in Comsol. It is believed to be the highest ever measured zT at a temperature which is modest (e.g., at about 150° C.). Previous devices have provided significantly lower values of zT at much higher temperatures, which makes the packaging much more challenging and may require brazing operations in non-oxidizing atmospheres. Hence, the embodiments herein provide thermoelectric semiconductor materials that drive the need for a unipolar TEG.

For a single thermocouple pair, an increase in power output is achieved for the device by thermal and electrical injection on the sidewalls of the pellets. Two cases are examined, where: (1) the pellets have matching sidewall metallizations; and (2) the effect of adding metallized sidewalls of the same thickness incrementally until all sidewalls are metallized. Each variation has unique effects in increasing device power output through thermal focusing. Indeed, contrary to the traditional practice in fabrication methods where there is an expectation of partial electrical shorting along the sidewalls that results in a reduction of device power output, there is an advantage to partially metallizing the sidewalls of a semiconductor pellet. By leaving a narrow gap 110, or slit, in the metallization of the sidewalls between the top and bottom metal electrode (e.g., to avoid electrical shorting) results in significantly increased thermoelectric power generation through thermal focusing (a.k.a. thermal lensing). In some embodiments, a metallization gap width of 50 microns is used with a uniform metallization surrounding the pellets with a thickness of about 1 mm on all four sidewalls of antimony telluride-based thermoelectric pellets, positioned symmetrically around the pellet.

Additionally, the fraction of pellet height of the metal sidewalls of the pellet thickness was examined with symmetric metal sidewall coverage on all four pellet sides for a P type pellet, as shown in FIG. 4. In the case of using a metal on the sidewalls, the sidewalls need an aperture, or gap, about a perimeter of the pellets at some predetermined height which exposes the pellets and breaks the electrical continuity between the top and bottom electrodes. That is, the aperture electrically isolates a top portion of the metal layer from a bottom portion of the metal layer of each P type semiconductor pellet. Yet the metal layer still remains on the sidewalls above and below the aperture. Such an aperture can be made by laser ablation along the sidewalls after metallization of the pellets.

A dual 3D printed copper pellet carrier can be fabricated and used to bond the P type pellet pairs to a copper carrier, where the height of a retainer is made to within about 75-80% of the pellet height. A sufficient amount of solder may be dispensed in each pellet retainer recess. The aperture 110 width can be as narrow as 50 microns. When using a relatively small aperture 110 on the sidewall metals, there can be two focusing effects depending on the location of the aperture 110. A narrow aperture 110 located around the pellet at the center of the sidewalls and in parallel to the top surface of the pellet, makes for two thermal focusing effects, one near the top side of the pellet and one near the bottom side of the pellet. The center of the aperture 110 located at the center of the of the sidewalls results in higher power output than the other locations for the aperture.

Surface mount technology for assembling metallized thermoelectric semiconductor pellets can be used, as with the other components in a TEG module, including the copper pellet carrier. One method of assembly depends on the materials, size and thickness of the pellets, and ease of handling. Automated techniques in module assembly can result in a cost-effective method with robotic pick and place for high-volume manufacturing. Metallized pellets in the size range of several millimeters on an edge and about 5 mm thick and roughly 6×6 mm square can be placed in matrix (JEDEC) trays where pick and place robots can build a TEG module (or cartridge) consisting of hundreds of pellets in a few minutes. Pellets in this size range have a distinct advantage in that they are easily handled and tracked by operators necessary in certain process operations, where the process may not be fully automated. Some methods of metallization are more cost effective also, especially if semi-automated techniques are in place to a reasonable extent. Electroplating is one such method, and the thickness of the metal electrode layers are easily controlled within the electroplating or electroless plating process.

### Geometric Effects and the Thermoelectric Effect

Thermoelectric material produces a Seebeck voltage corresponding to its intrinsic or doped material properties, temperature gradient across the material, and the internal isotherms of the pellet. When connected in a series circuit, the pellet's electrical current directly corresponds to the cross-sectional area of the semiconductor material and series connection contact. When in a device, the thickness of pellet correlates to the thermal conduction through from hot to cold side.

The modeled thermoelectric pair device implements real device geometric properties. When modeled, the thermoelectric pair device used verified and measured physical properties of an N type and P type semiconductor, bismuth selenium telluride and antimony bismuth telluride, respectively. No electrical contact resistance between the metal electrodes and the semiconductors, and no contact heat transfer coefficients were used in modeling the TEGs herein. The model includes the temperature dependent properties of relevant packaging materials, such as copper, aluminum, and the measured properties of semiconductors. Measurements were made on square bars of the sintered semiconductors and data collected for the Seebeck coefficient, electrical, and thermal conductivity as function of temperature. The power output of a pellet is proportional to the cross-sectional area of the thermal gradients within the bulk of the pellet.

In some embodiments, a parametric study focused on: (1) the analysis of the physical properties of the vertical interconnects; and (2) the nature of the output electrodes, one P type pellet and one N type pellet. The P type pellet at the output should be made to match the current generated by P type pairs, which requires approximately twice the area of the one P type pellet plus the advantage of the TLEC effect.

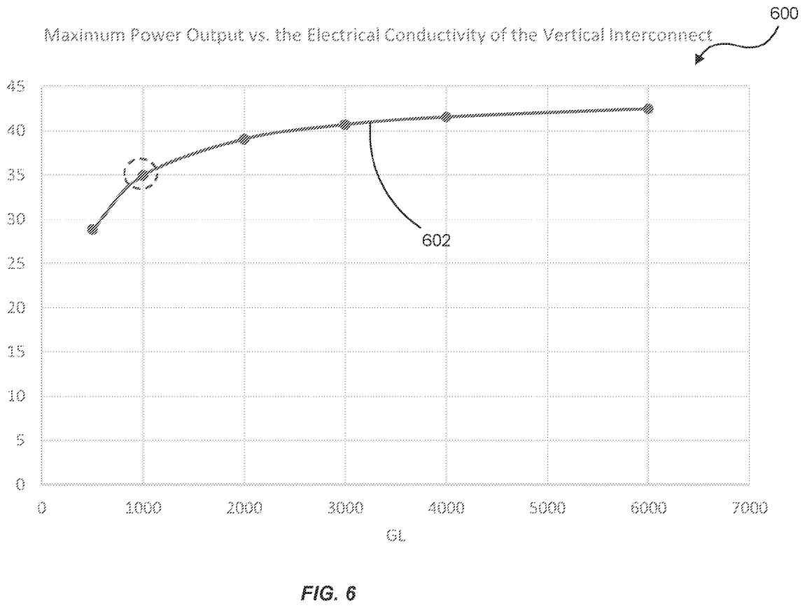

Additionally, the area of the N type pellet should be large enough to carry the current generated by the output P type pellet. Since the electrical resistivity of the N type pellet is greater than the P type resistivity, as shown in FIG. 6, the N type pellet area should be about 1.31 larger than the P type pellet area to balance the load. Parametric runs may be needed to maximize the output of these pellets and balance the P type pairs with the output pellets. Again, the ratio of the N type to the P type resistivities is shown in FIG. 6.

In accordance with this optimization, the parameters GL, TL which represent respectively, the electrical and thermal conductivities of the vertical interconnects, should be studied simultaneously because all parameters can determine the maximum power output. Thus, several parametric dimensions influence the output: GL, TL, RL (resistive load for maximum power), N type output area, P type output area.

Output pellets (e.g., n type pellet 106) generally do not have a large influence on output performance of the TEG, at least less than the P type pellet pairs 104.

### The Effects of Thermal Focusing

In accordance with the bonding metal sidewalls to a thermoelectric pellet for thermal conduction, and the area of the thermal gradients, an alternative method is suggested to effectively increase the active volume of the thermoelectric effect to acquire more electrical power. This method involves the modification of the thermal gradients within the pellet by use of metal sidewall layers that provide thermal focusing. Metal is generally thermally and electrically very conductive compared to thermoelectric semiconductors. These physical properties provide a distinct advantage in controlling the isothermal fields with the semiconductor, which in turn controls thermoelectric power generation (or cooling). The control of the thermal gradients increases the effective volume of thermoelectric effect by changing the shape of the isotherms to a three-dimensional curvature of the isotherms. By injecting heat and electrical energy through the sidewalls of a pellet coated with a relatively thick film of metal, thermoelectric power increases by an increased effective volume with pellet. The curvature of thermal gradients resulting from the thermal focusing effect changes shape and occurs well within the internal volume of the pellet.

In order to prevent thermal shorting from the hot side 108 to the cold side substrate 112 by the vertical interconnects 102, a new material may be needed. One candidate material for the vertical interconnect material is graphene oxide or reduced graphene oxide. This may have the potential to tune in the low thermal conductivity, which can be as low 0.027 W/m-K. The graphene material can be doped with copper to tune its electrical conductivity to meet the requirements of conductance in the vertical interconnects 102.

The shading in the accompanying figures is generally provided to clarify the boundaries between adjacent elements and also to facilitate legibility of the figures. Accordingly, neither the presence nor the absence of shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

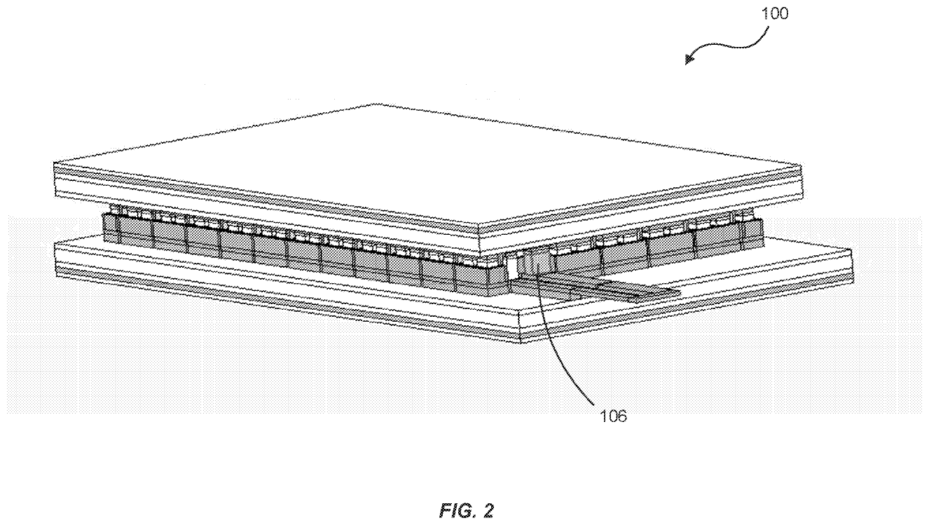

FIG. 2 is another perspective view of the TEG package of FIG. 1 illustrating P type semiconductor pellet pairs 104. In this embodiment, the P type pellet pairs 104 are adjacent to one another. One N type pellet 106 is configured at the output of the TEG 100. The N type pellet 106 is used to reverse the electrical current of the TEG 100.

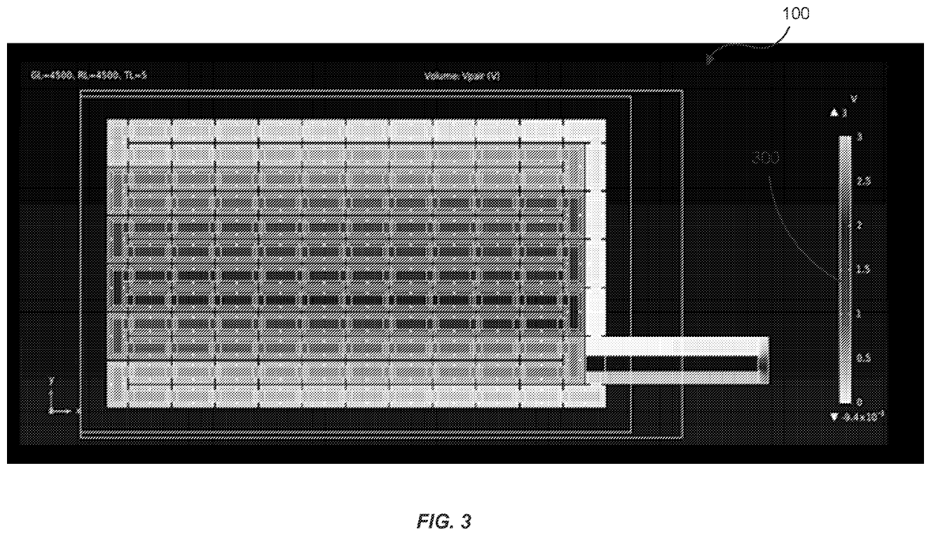

FIG. 3 is an overhead view of a TEG package 100 illustrating the voltage throughput 300. In this embodiment, the TEG module 100 has a GL=4500 and a TL=5.

FIG. 4 is a graph 400 illustrating the zT figure of merit of the P type pellets 104 and the N type pellet 106 as a function of temperature. In this embodiment, the zT value of the P type pellet 104 is illustrated with the current 402. And the zT value of the N type pellet 106 is illustrated with the curve 404. Pairs of the P type pellets 104 inside a copper thermal lensing electrode indicate that the thermal focusing effect is the source of power.

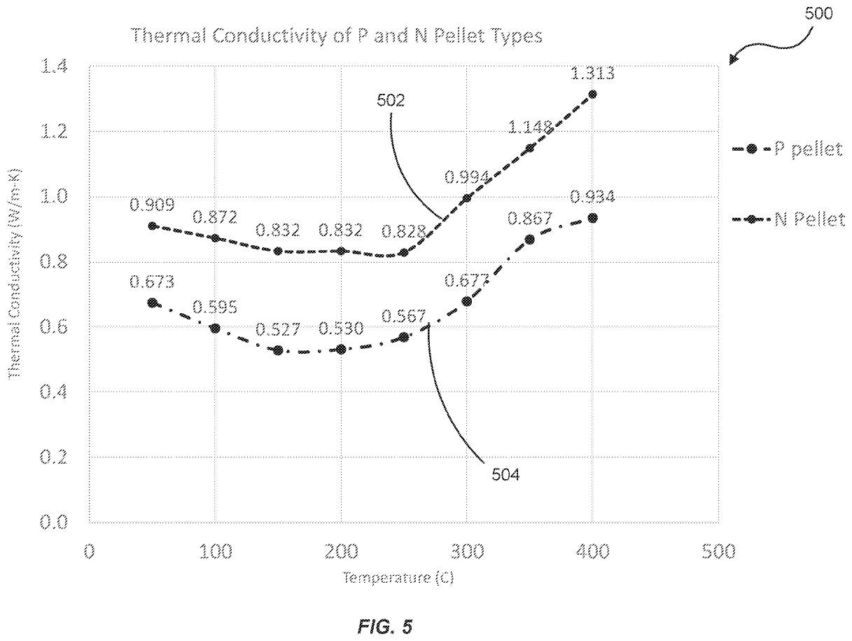

FIG. 5 is a graph 500 illustrating thermal conductivity of P type pellets 104 and N type pellets 106. In this embodiment, the thermal conductivity of the P type pellets 104 is illustrated with the curve 502. And the thermal conductivity of the N type pellets 106 is illustrated with the curve 504.

FIG. 6 is a graph 600 illustrating how the electrical conductivity of vertical interconnect 102 improves the power output 602. Graph 600 reveals the nature of how the electrical conductivity of the vertical interconnects 102 determines the power output. Generally, the power output increases with the electrical conductivity until there is a saturation point, and higher values do not contribute to more power. Hence, a satisfactory value that provides sufficient electrical conduction is sought. Graphite electrical conductivity is normally given as GL=3e³ [S/m], GL is a parametric variable and makes the electrical conductivity larger by multiplication, e.g., GL=N*3e³ [S/m], where N is an integer multiplier value. The electrical conductivity of graphite is generally too low for the generator to produce sufficient power, so a larger value is needed. Here, 1000 is chosen so that the physical value is 3000 e³/(Ωm) or the resistivity is 1 e⁻⁶ Ωm=1 e³⁻ Ωcm=1e³ μΩcm. Thermal conductivity is chosen by using the thermal conductivity as low as possible to avoid thermal shorting between the hot and cold sides. A value of 0.028 W/(mK) was used to determine the behavior of the variation of the electrical conductivity.

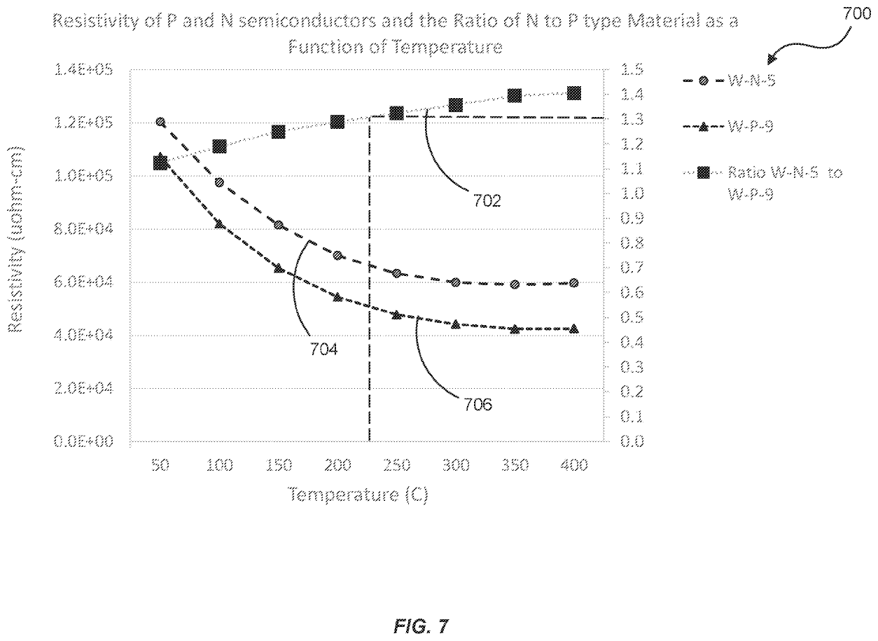

FIG. 7 is a graph 700 illustrating resistivity of P type pellets 104 and N type pellets 106 and the ratio of P type pellets 104 and N type pellets 106 as a function of temperature. In this embodiment, the P type pellets 104 are represented by the curve 706, the N type pellets 106 are represented by the curve 704, and the ratio as a function of temperature is represented by the curb 702.

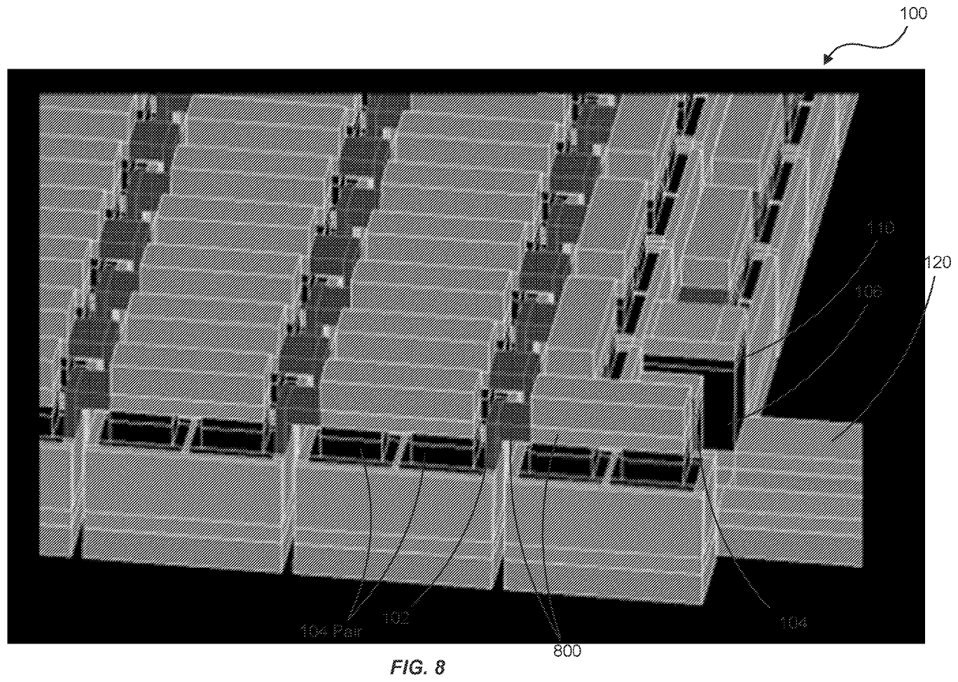

FIG. 8 is a perspective view of a TEG package 100 illustrating details of the vertical interconnects 102 and the horizontal interconnects 800. Each of the vertical interconnects 102 and the horizontal interconnects 800 may be configured from graphene oxide or reduced graphene oxide. Again, this may have the potential to tune in the low thermal conductivity, which can be as low as 0.027 W/m-K. The graphene material can be doped with copper to tune its electrical conductivity to meet the requirements of conductance in the vertical interconnects 102.

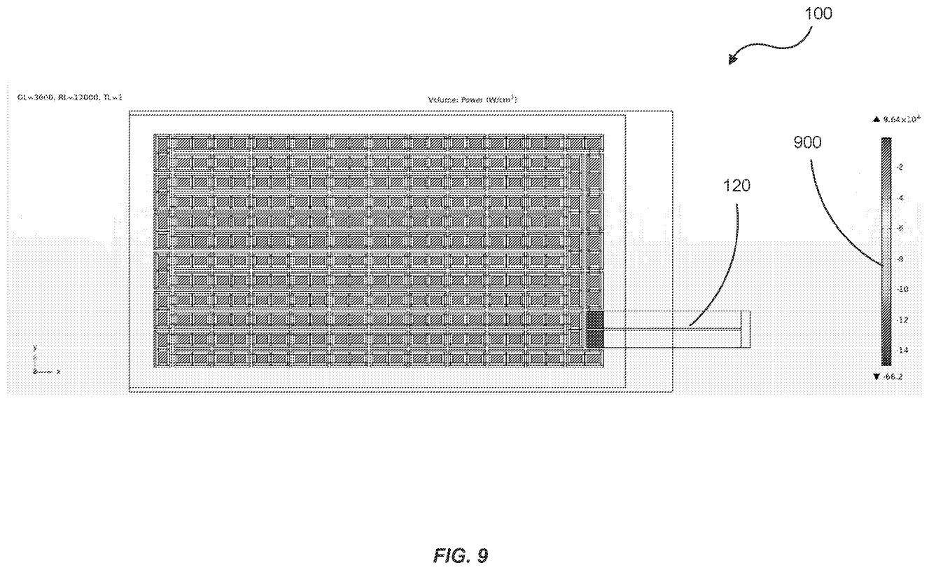

FIG. 9 is an overhead view of a TEG package illustrating power density 900 as a function of electrical conductivity (GL) and resistive load (RL). The output electrode 120 provides a relatively high power density.

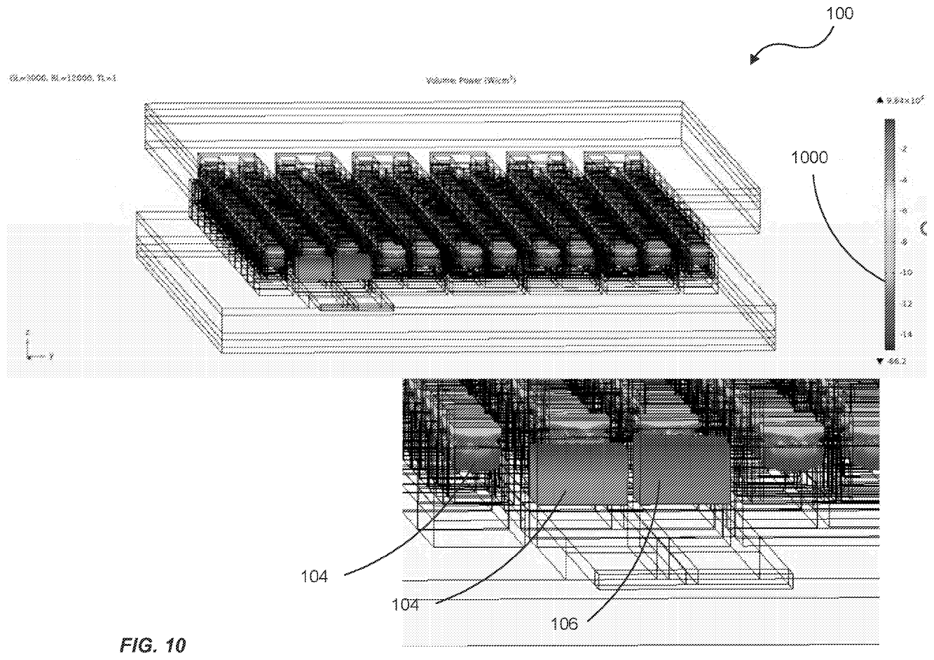

FIG. 10 is an exploded view of a TEG package 100 illustrating power density 1000 of the TEG package 100.

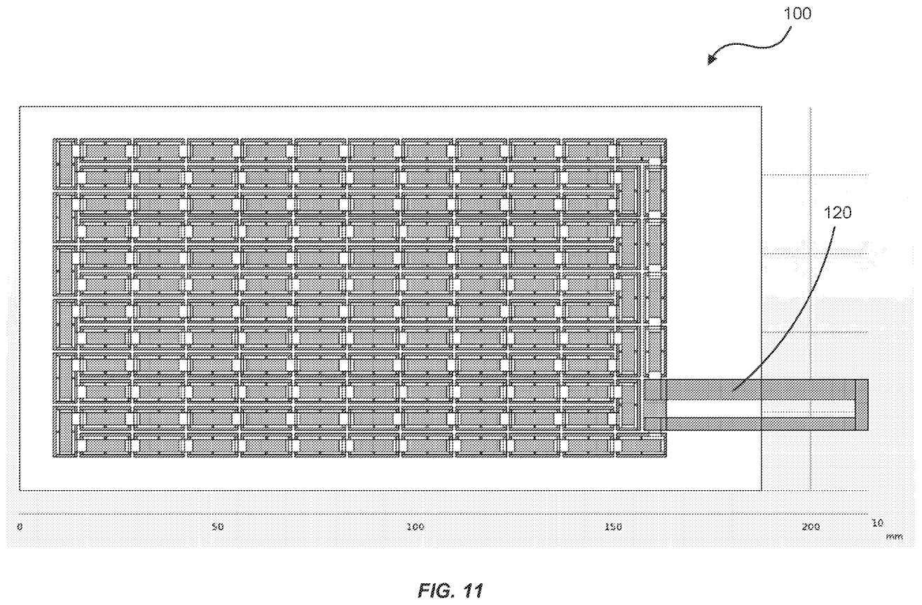

FIG. 11 is another overhead view of a TEG package 100 in the form of a unipolar thermal lensing electrode (UTLEC).

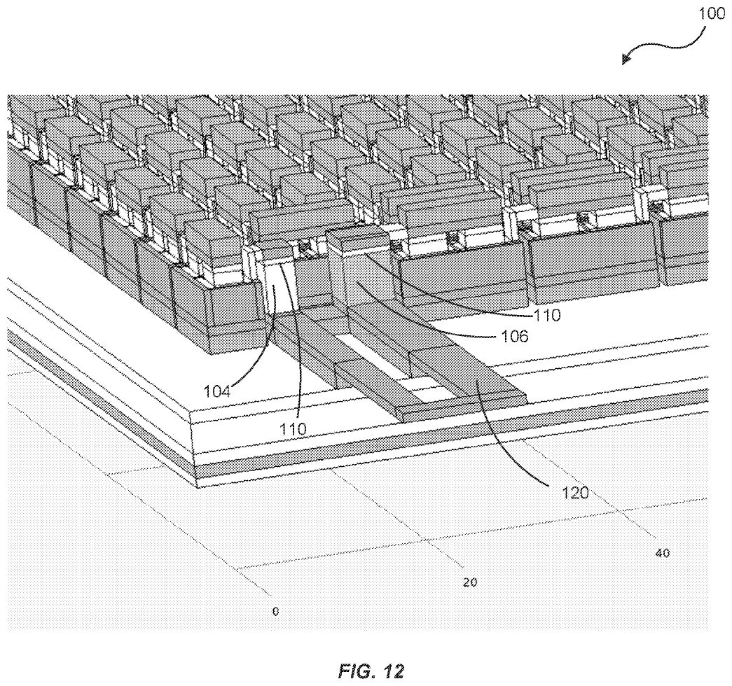

FIG. 12 is a perspective and exploded view of a TEG package shown without the upper plate and with one N type pellet 106 that reverses current at an output electrode 120.

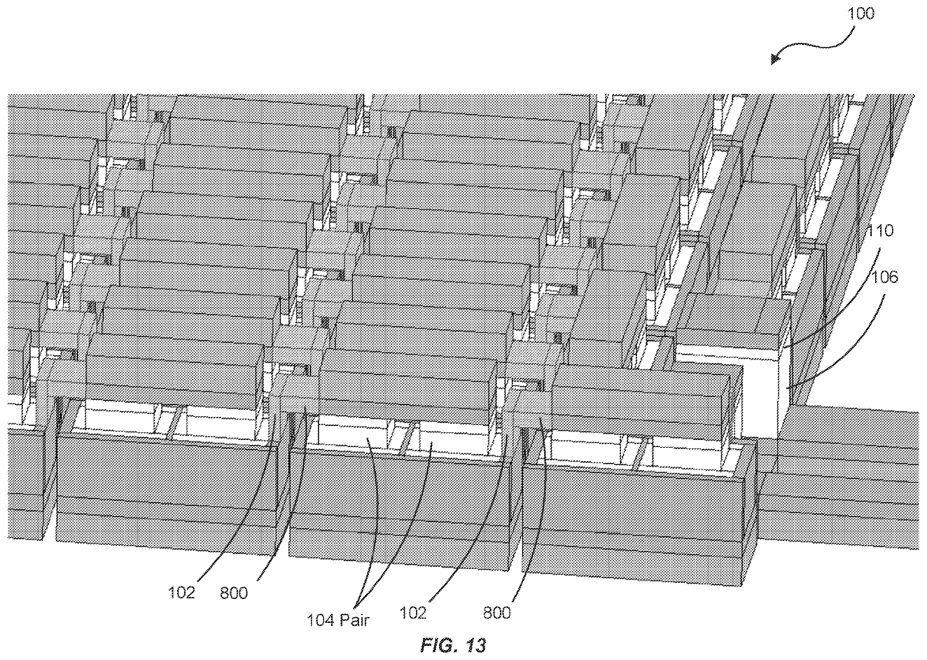

FIG. 13 is a perspective and exploded view of a TEG package shown without the upper plate and illustrating vertical interconnects 102 between P type pellet pairs 104.

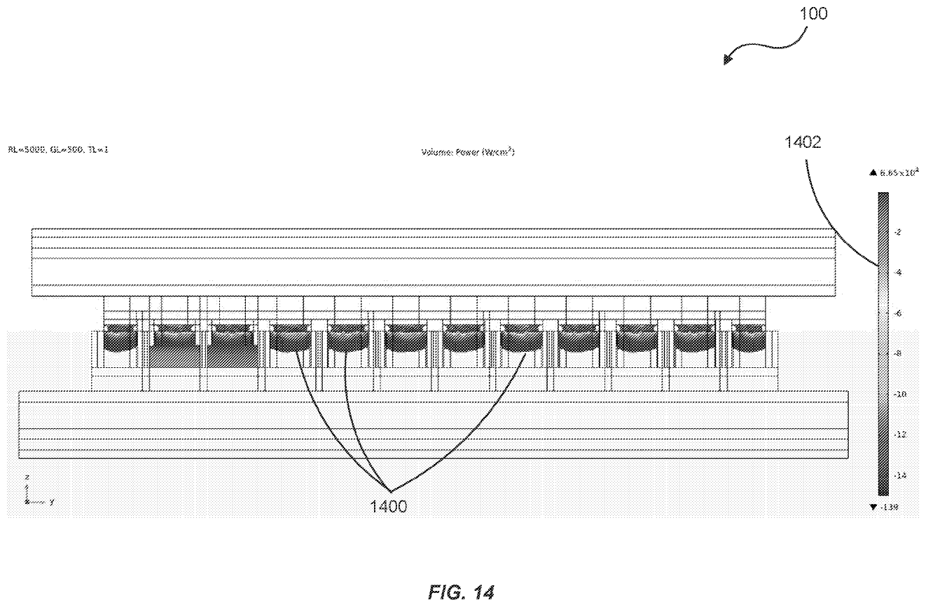

FIG. 14 is a cross sectional view of a TEG package 100 illustrating a curvature of the power density distribution 1400/1402 induced by the TEG package components. The curvature of the power density distribution is induced by the thermal lensing electrode (TLEC) component.

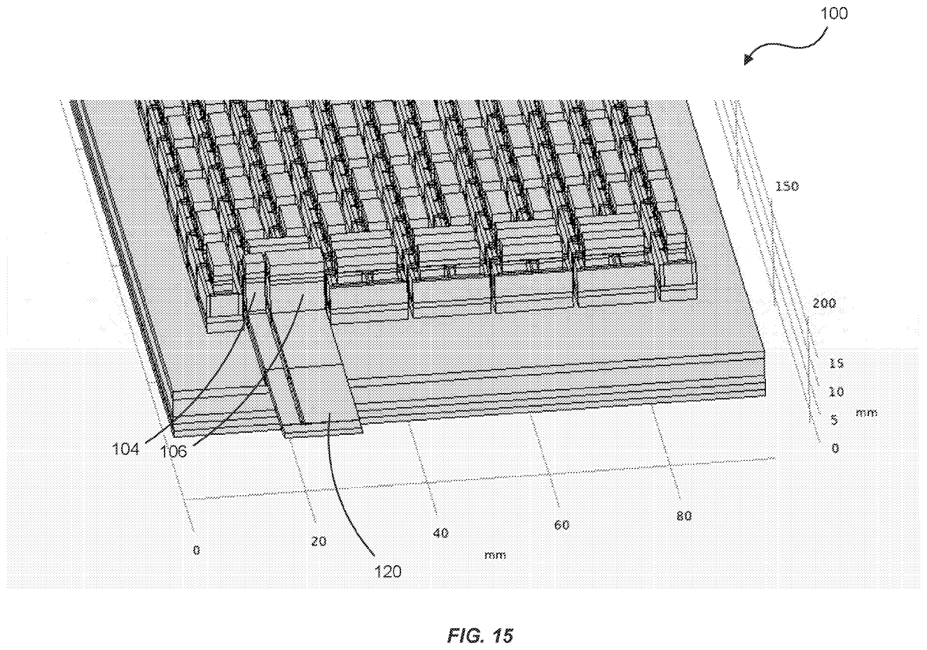

FIG. 15 is a perspective and exploded view of a TEG package 100 shown without the upper plate and size variations in the output electrodes 120.

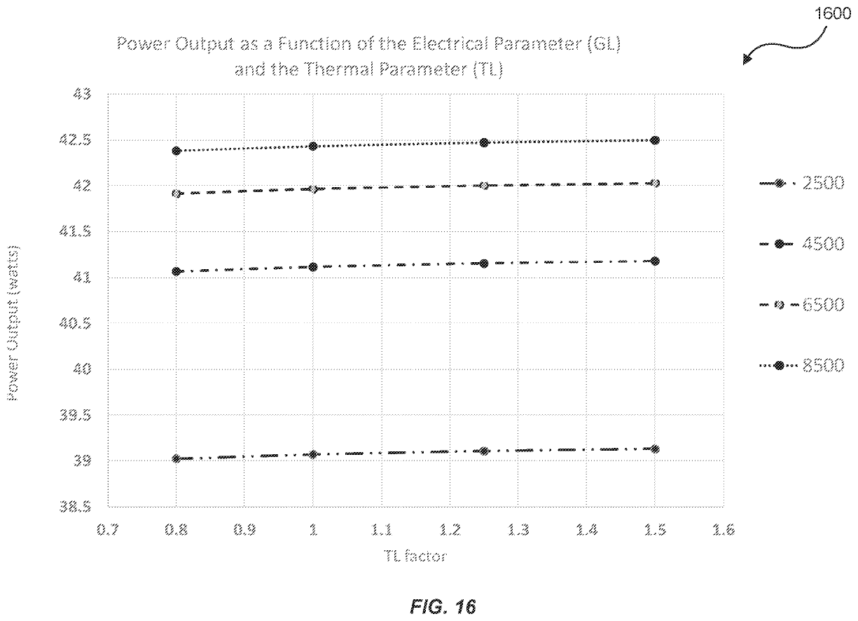

FIG. 16 is a graph 1600 illustrating power output of the TEG package 100 as a function of electrical conductivity (GL) and the thermal conductivity (TL). In this embodiment, low thermal conductivity to normal thermal conductivity (0.027 w/m-K) is illustrated. GL increases the electrical conductivity of the vertical electrodes 102, increasing power output. TL allows more heat through the vertical interconnect 102, which should decrease power output because of thermal shorting. However, for this range of TL, it does not influence the heat loss. In fact, the power output is more strongly influenced by is overcome by the increase in GL.

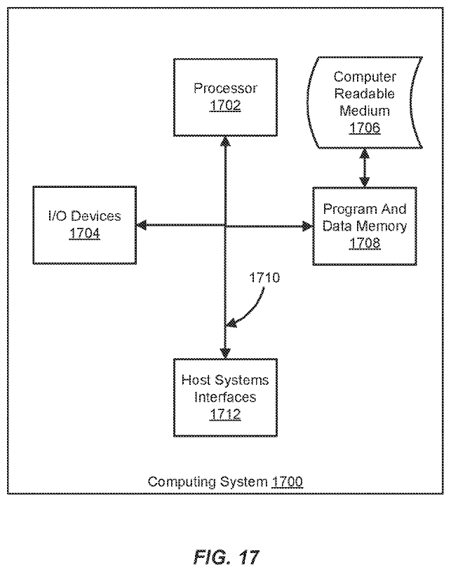

Any of the above embodiments herein may be rearranged and/or combined with other embodiments. Accordingly, the concepts herein are not to be limited to any particular embodiment disclosed herein. Additionally, the embodiments can take the form of entirely hardware or comprising both hardware and software elements. Portions of the embodiments may be implemented in software, which includes but is not limited to firmware, resident software, microcode, etc. For example, a controller or other computing system may be directed by software to control or otherwise manage the power output of the TEG embodiments disclosed herein. FIG. 17 illustrates one computing system 1700 in which a computer readable medium 1706 may provide instructions for performing any of the methods disclosed herein.

Furthermore, the embodiments can take the form of a computer program product accessible from the computer readable medium 1706 providing program code for use by or in connection with a computer or any instruction execution system. For the purposes of this description, the computer readable medium 1706 can be any apparatus that can tangibly store the program for use by or in connection with the instruction execution system, apparatus, or device, including the computing system 1700.

The medium 1706 can be any tangible electronic, magnetic, optical, electromagnetic, infrared, or semiconductor system (or apparatus or device). Examples of a computer readable medium 1706 include a semiconductor or solid state memory, magnetic tape, a removable computer diskette, a random access memory (RAM), NAND flash memory, a read-only memory (ROM), a rigid magnetic disk and an optical disk. Some examples of optical disks include compact disk-read only memory (CD-ROM), compact disk-read/write (CD-R/W) and digital versatile disc (DVD).

The computing system 1700, suitable for storing and/or executing program code, can include one or more processors 1702 coupled directly or indirectly to memory 1708 through a system bus 1710. The memory 1708 can include local memory employed during actual execution of the program code, bulk storage, and cache memories which provide temporary storage of at least some program code in order to reduce the number of times code is retrieved from bulk storage during execution. Input/output or I/O devices 1704 (including but not limited to keyboards, displays, pointing devices, etc.) can be coupled to the system either directly or through intervening I/O controllers. Network adapters may also be coupled to the system to enable the computing system 1700 to become coupled to other data processing systems, such as through host systems interfaces 1712, or remote printers or storage devices through intervening private or public networks. Modems, cable modem and Ethernet cards are just a few of the currently available types of network adapters.

What is claimed is:

1. A thermoelectric generator, comprising:
a plurality of pairs of P type semiconductor pellets configured on a substrate and interconnected by vertical and horizontal interconnects;
an N type semiconductor pellet configured on the substrate; and
an electrode, wherein the N type semiconductor pellet is operable to reverse electrical current to at least one of the P type semiconductor pellets through the electrode.

2. The thermoelectric generator of claim 1, wherein:
the P type semiconductor pellets have a zT value of about 2.6.

3. The thermoelectric generator of claim 1, wherein:
at least the vertical interconnects are configured from graphene oxide, reduced graphene oxide, an aerogel, a metal sidewall on an insulator, or a metal doped BiTe pellet.

4. The thermoelectric generator of claim 1, wherein:
the vertical interconnects are operable to direct electrical current as a top-to-bottom series circuit between neighboring P type semiconductor pellet pairs.

5. The thermoelectric generator of claim 1, wherein:
the vertical interconnects comprise a shape including at least one of a z-shaped strip, a cuboid, a cylinder, a sphere, a trapezoid, or a pyramid.

6. The thermoelectric generator of claim 1, wherein:
the P type semiconductor pellets arc metallized with a metal layer surrounding each of the P type semiconductor pellets;
each metal layer comprises an aperture that exposes its respective P type semiconductor pellet about a perimeter of the P type semiconductor pellet at a predetermined sidewall height of the P type semiconductor pellet; and
the metal layer remains at the sidewall of each P type semiconductor pellet.

7. The thermoelectric generator of claim 1, wherein:
the P type semiconductor pellets are configured with a non-metal layer that is thermally conductive and electrically insulative surrounding each of the P type semiconductor pellets;
each non-metal layer comprises an aperture that exposes its respective P type semiconductor pellet about a perimeter of the P type semiconductor pellet at a predetermined sidewall height of the P type semiconductor pellet; and
the non-metal layer remains at the sidewall of each P type semiconductor pellet.

8. The thermoelectric generator of claim 6, wherein:
the metal layer comprises copper, titanium, tungsten, nickel-phosphorous, or a chromium alloy.

9. The thermoelectric generator of claim 7, wherein:
the non-metal layer comprises thermally conductive high temperature epoxies and adhesives.

10. The thermoelectric generator of claim 6, wherein:
the aperture electrically isolates a top portion of the metal layer from a bottom portion of the metal layer of each P type semiconductor pellet.

11. The thermoelectric generator of claim 6, further comprising:
a plurality of metal containers, each being thermally and electrically bonded to the metal layer of one of the P type semiconductor pellets, wherein the metal containers are configured between the metal layers and the substrate.

12. The thermoelectric generator of claim 6, wherein:
the apertures provide a non-linear effect on a power output of the thermoelectric generator by modifying an isotherm surface curvature within the P type semiconductor pellets.

13. The thermoelectric generator of claim 12, wherein:
the isotherm surface curvature within the P type semiconductor pellets is operable to increase an effective surface area of a thermoelectric effect within a volume of the P type semiconductor pellets via heat injection through the sidewall of the P type semiconductor pellets.

14. The thermoelectric generator of claim 1, wherein:
the P type semiconductor pellets are configured in a shape that is operable to increase a thermal lensing effect of the thermoelectric generator.

15. The thermoelectric generator of claim 11, wherein:
the shape is cuboid.

16. The thermoelectric generator of claim 11, wherein:
the shape is cylindrical.
